(19) United States
(12) Patent Application Publication
(10) Pub. No.: US 2018/0209066 A1
(43) Pub. Date: Jul. 26, 2018

(54) RUTILE-TYPE NIOBIUM OXYNITRIDE, METHOD FOR PRODUCING SAME, AND SEMICONDUCTOR STRUCTURE

(71) Applicant: Panasonic Corporation, Kadoma-shi, Osaka (JP)

(72) Inventors: Ryosuke KIKUCHI, Osaka (JP); Kazuhito HATO, Osaka (JP); Tetsuya HASEGAWA, Kanagawa (JP); Yasushi HIROSE, Kanagawa (JP)

(21) Appl. No.: 15/745,957

(22) PCT Filed: Jul. 21, 2016
(86) PCT No.: PCT/JP2016/003412

§ 371 Date: Jan. 18, 2018

(30) Foreign Application Priority Data
Jul. 23, 2015 (JP) 2015-145703

(51) Int. Cl. C30B 29/38; C01B 21/082; C30B 25/10; H01L 21/02; H01L 31/032; H01L 31/036; H01L 31/18

(52) U.S. Cl. CPC C30B 29/38; C01B 21/0821; C30B 25/105; H01L 21/02422; H01L 21/02565; H01L 21/02609; C01P 2002/84; H01L 31/032; H01L 31/036; H01L 31/18; C01P 2006/40; C01P 2002/77; C01P 2002/72; H01L 21/02631

(57) ABSTRACT

The present disclosure provides a rutile-type niobium oxynitride having a rutile-type crystal structure and represented by the chemical formula NbON. The present disclosure also provides a semiconductor structure (100) including: a substrate (110) having at least one principal surface composed of a rutile-type compound having a rutile-type crystal structure; and a niobium oxynitride (for example, a rutile-type niobium oxynitride film (120)) grown on the one principal surface of the substrate (110), the niobium oxynitride having a rutile-type crystal structure and being represented by the chemical formula NbON.

### TECHNICAL FIELD

The present disclosure relates to a rutile-type niobium oxynitride, a method for producing the same, and a semiconductor structure including a rutile-type niobium oxynitride.

### BACKGROUND ART

Irradiation of optical semiconductors with light produces electron-hole pairs in the optical semiconductors. Such optical semiconductors are promising because they can be used in various applications such as: solar cells in which the paired electron and hole are spatially separated to extract the photovoltaic power in the form of electrical energy; photocatalysts for use in producing hydrogen directly from water using sunlight; and photodetection elements. For example, Patent Literature 1 discloses an optical semiconductor capable of effectively using long-wavelength light, the optical semiconductor being a niobium oxynitride having a baddeleyite-type crystal structure and represented by the composition formula NbON. Patent Literature 1 states that the niobium oxynitride having a baddeleyite structure has the ability to absorb light with a wavelength of 560 nm or less.

### CITATION LIST

### Patent Literature

Patent Literature 1: JP 5165155 B2

### SUMMARY OF INVENTION

### Technical Problem

A material capable of absorbing longer-wavelength light than the conventional optical semiconductor mentioned above has been demanded, for example, to achieve more efficient use of sunlight. It is therefore an object of the present disclosure to provide a novel material capable of absorbing longer-wavelength light and capable of functioning as an optical semiconductor.

### Solution to Problem

The present disclosure provides a rutile-type niobium oxynitride having a rutile-type crystal structure and represented by the chemical formula NbON.

### Advantageous Effects of Invention

According to the present disclosure, it is possible to provide a novel material capable of absorbing longer-wavelength light than the hitherto existing niobium oxynitride and capable of functioning as an optical semiconductor.

### BRIEF DESCRIPTION OF DRAWINGS

FIG. 1 shows two patterns of the crystal structure of a rutile-type niobium oxynitride.

FIG. 2 shows two patterns of the crystal structure of a rutile-type niobium oxynitride which are obtained by crystal structure optimization using first-principles calculation.

FIG. 3A shows a result of calculation of the band dispersion of a baddeleyite-type niobium oxynitride.

FIG. 3B shows a result of calculation of the band dispersion of a rutile-type niobium oxynitride having a crystal structure corresponding to that of rutile-type niobium oxynitride (1) shown in FIG. 2.

FIG. 3C shows a result of calculation of the band dispersion of a rutile-type niobium oxynitride having a crystal structure corresponding to that of rutile-type niobium oxynitride (2) shown in FIG. 2.

FIG. 4 shows a cross-sectional view of a semiconductor structure according to an embodiment.

FIG. 5 shows a X-ray diffraction pattern obtained by X-ray diffraction measurement performed for a niobium oxynitride film of Example 1 according to a 2θ-ω scan method.

FIG. 6 shows a result of measurement of the light absorbance of the niobium oxynitride film of Example 1.

### DESCRIPTION OF EMBODIMENTS

A first aspect of the present disclosure is a rutile-type niobium oxynitride having a rutile-type crystal structure and represented by the chemical formula NbON.

The rutile-type niobium oxynitride as set forth in the first aspect has a rutile-type crystal structure and is a novel material which has hitherto been unknown. This rutile-type niobium oxynitride is capable of absorbing longer-wavelength light than the hitherto existing niobium oxynitride which has a baddeleyite-type crystal structure. Additionally, this rutile-type niobium oxynitride features excellent electron mobility and excellent hole mobility and has the advantageous property of permitting easy movement of electrons and holes generated by photoexcitation. The most stable crystal structure for niobium oxynitrides is of the baddeleyite type. The rutile-type niobium oxynitride as set forth in the first aspect of the present disclosure has a metastable crystal structure and cannot be obtained by any common known process for producing niobium oxynitrides. Hitherto, the rutile-type crystal structure has not even been considered as a crystal structure that niobium oxynitrides can have instead of the baddeleyite-type crystal structure.

According to a second aspect, for example, the rutile-type niobium oxynitride as set forth in the first aspect may be a semiconductor.

The rutile-type niobium oxynitride as set forth in the second aspect can be used as a semiconductor in various technical fields.

According to a third aspect, for example, the rutile-type niobium oxynitride as set forth in the second aspect may be an optical semiconductor.

The rutile-type niobium oxynitride as set forth in the third aspect can be used as an optical semiconductor in various technical fields.

According to a fourth aspect, for example, the rutile-type niobium oxynitride as set forth in any one of the first to third aspects may be oriented in a (110) plane.

The rutile-type niobium oxynitride as set forth in the fourth aspect can exhibit higher performance in terms of light absorption and ease of movement of electrons and holes.

A fifth aspect of the present disclosure is a semiconductor structure including: a substrate having at least one principal surface composed of a rutile-type compound having a rutile-type crystal structure; and a rutile-type niobium oxynitride grown on the one principal surface of the substrate, wherein the rutile-type niobium oxynitride is as defined in any one of the first to fourth aspects.

In the semiconductor structure as set forth in the fifth aspect, the rutile-type niobium oxynitride as set forth in any one of the first to fourth aspects is provided on the substrate. Thus, the semiconductor structure as set forth in the fifth aspect is capable of absorbing longer-wavelength light than semiconductor structures provided with a hitherto known niobium oxynitride, and has the advantageous property of permitting easy movement of electrons and holes generated by photoexcitation.

According to a sixth aspect, for example, in the semiconductor structure as set forth in the fifth aspect, the substrate may be a titanium oxide substrate.

In the semiconductor structure as set forth in the sixth aspect, the rutile-type niobium oxynitride grown on the substrate can exhibit higher performance in terms of light absorption and ease of movement of electrons and holes.

According to a seventh aspect, for example, in the semiconductor structure as set forth in the fifth or sixth aspect, the rutile-type niobium oxynitride may be oriented in a (110) plane.

In the semiconductor structure as set forth in the seventh aspect, the rutile-type niobium oxynitride grown on the substrate can exhibit higher performance in terms of light absorption and ease of movement of electrons and holes.

According to an eighth aspect, for example, in the semiconductor structure as set forth in any one of the fifth to seventh aspects, the rutile-type compound of the substrate may be oriented in a (110) plane.

In the semiconductor structure as set forth in the eighth aspect, the rutile-type niobium oxynitride grown on the substrate can exhibit higher performance in terms of light absorption and ease of movement of electrons and holes.

A ninth aspect of the present disclosure is a rutile-type niobium oxynitride production method for producing the rutile-type niobium oxynitride as set forth in any one of the first to fourth aspects, the method including: preparing a substrate having at least one principal surface composed of a rutile-type compound having a rutile-type crystal structure; and growing a rutile-type niobium oxynitride on the one principal surface of the substrate by epitaxial growth.

The production method as set forth in the ninth aspect is capable of producing the rutile-type niobium oxynitride as set forth in any one of the first to fourth aspects.

According to a tenth aspect, for example, in the production method as set forth in the ninth aspect, the epitaxial growth may be carried out by pulsed laser deposition.

The production method as set forth in the tenth aspect is capable of easily producing a rutile-type niobium oxynitride that exhibits higher performance in terms of light absorption and ease of movement of electrons and holes.

According to an eleventh aspect, for example, in the production method as set forth in the tenth aspect, a target composed of niobium oxide may be used, and the rutile-type niobium oxynitride may be grown by a reaction of the target having been laser-ablated with oxygen and nitrogen radical.

The production method as set forth in the eleventh aspect is capable of easily producing a rutile-type niobium oxynitride that exhibits higher performance in terms of light absorption and ease of movement of electrons and holes.

Hereinafter, embodiments of the present disclosure will be described in detail with reference to the drawings. The embodiments described below are only illustrative, and the present disclosure is not limited to the embodiments.

(Rutile-Type Niobium Oxynitride)

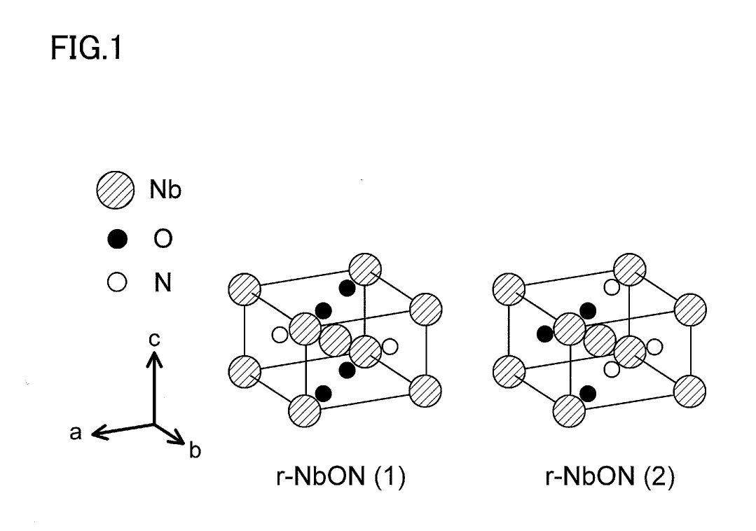

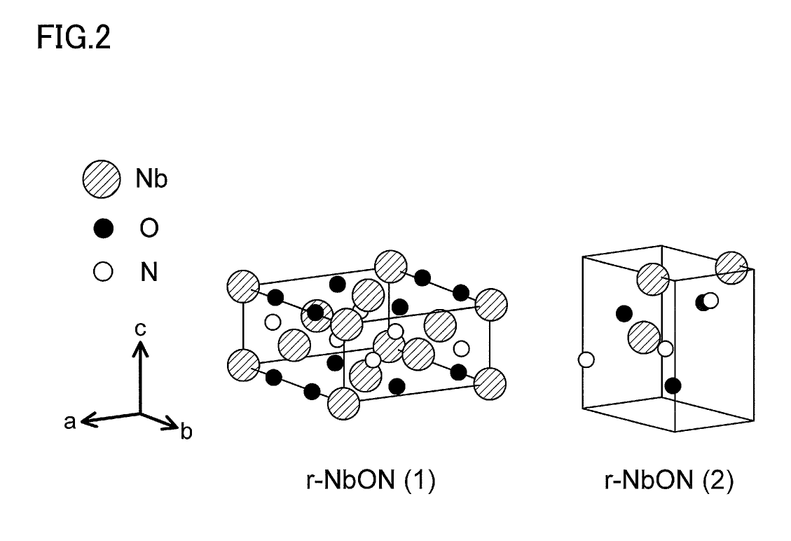

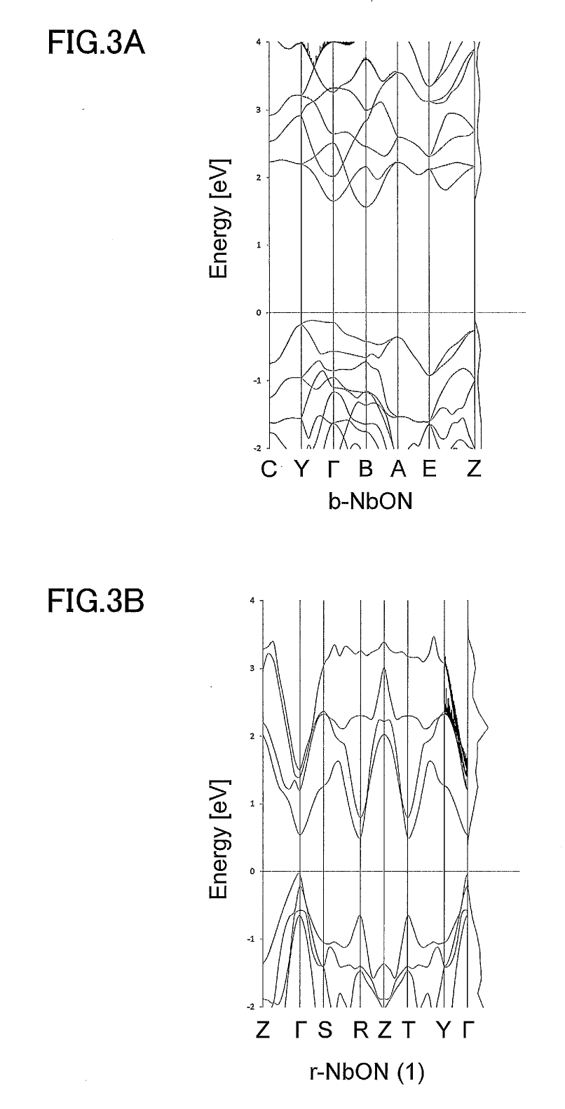

Crystal structures of a rutile-type niobium oxynitride (which may hereinafter be referred to as “r-NbON”) are shown in FIG. 1. As shown in FIG. 1, possible crystal structures of the rutile-type niobium oxynitride are the two patterns, r-NbON (1) and r-NbON (2), which differ in the positions of niobium atoms, oxygen atoms, and nitrogen atoms. The crystal structure of a baddeleyite-type niobium oxynitride (which may hereinafter be referred to as “b-NbON”) and the crystal structures of r-NbON (1) and r-NbON (2) shown in FIG. 1 were subjected to crystal structure optimization using first-principles calculation. First-principles band calculation was also carried out for b-NbON, r-NbON (1), and r-NbON (2) subjected to the crystal structure optimization. The first-principles calculation was performed using projector augmented wave (PAW) method on the basis of the density functional theory. In this calculation, a functional called GGA-PBE was used to describe the electron density representing the exchange-correlation term associated with interaction between electrons. The crystal structures of r-NbON (1) and r-NbON (2) resulting from the crystal structure optimization are shown in FIG. 2. Table 1 shows space groups, lattice constants, and band gaps (denoted by “EG” in Table 1) for b-NbON, r-NbON (1), and r-NbON (2) resulting from the crystal structure optimization. Band dispersion curves obtained by first-principles calculation for b-NbON, r-NbON (1), and r-NbON (2) are shown in FIGS. 3A to 3C, respectively.

TABLE 1

| | Space group | a [Å] | b [Å] | c [Å] |
|---|---|---|---|---|
| b-NbON | P2₁/c | 4.955 | 5.014 | 5.157 |
| r-NbON (1) | Cmmm | 6.68 | 6.776 | 3.086 |
| r-NbON (2) | Pmn2₁ | 3.097 | 4.734 | 4.79 |
| | α [°] | β [°] | γ [°] | EG [eV] |
| b-NbON | 90 | 99.73 | 90 | 1.8 |
| r-NbON (1) | 90 | 90 | 90 | 0.87 |
| r-NbON (2) | 90 | 90 | 90 | 1.5 |

As seen from FIGS. 3B and 3C, it is suggested that r-NbON (1) and r-NbON (2) are both semiconductors having a band gap. Additionally, as shown in Table 1, the band gaps calculated for r-NbON (1) and r-NbON (2) are lower than that calculated for b-NbON. This suggests the possibility that r-NbON (1) and r-NbON (2) are semiconductors capable of absorbing longer-wavelength light than b-NbON. Based on the band dispersion curves shown in FIGS. 3A to 3C, the effective mass of electrons and the effective mass of holes can be determined from the curvature of the bottom of the conduction band and the curvature of the top of the valence band, respectively. Table 2 shows, for b-NbON, r-NbON (1), and r-NbON (2), the ratio between the effective mass and rest mass of electrons (electron effective mass/electron rest mass, denoted by “me*/m0” in Table 2) and the ratio between the effective mass of holes and the rest mass of electrons (hole effective mass/hole rest mass, denoted by “mh*/m0” in Table 2) in various directions. In Table 2, the term “VBM” refers to the valence band maximum, and the term “CBM” refers to the conduction band minimum.

TABLE 2

| Crystal structure | | me*/m0 | | mh*/m0 | | |
|---|---|---|---|---|---|---|
| b-NbON | Direction | B→Γ | B→A | VBM→Y | VBM→Γ | |
| | Calculation result | 1.2 | 1.1 | 3.5 | 4.6 | |
| r-NbON (1) | Direction | T→Z | T→Y | Γ→Z | Γ→S | Γ→Y |
| | Calculation result | 0.15 | 0.68 | 0.84 | 0.17 | 0.17 |
| r-NbON (2) | Direction | CBM→X | CBM→S | Γ→Z | Γ→X | |
| | Calculation result | 1.0 | 1.0 | 1.1 | 2.3 | |

The data shown in Table 2 lead to the expectation that r-NbON (1) and r-NbON (2) have a smaller electron effective mass and a smaller hole effective mass than b-NbON. This suggests the possibility that r-NbON is a material having excellent electron mobility and hole mobility and being able to absorb long-wavelength light as described above and therefore that r-NbON can serve as a useful optical semiconductor capable of, for example, highly efficient use of sunlight.

(Semiconductor Structure)

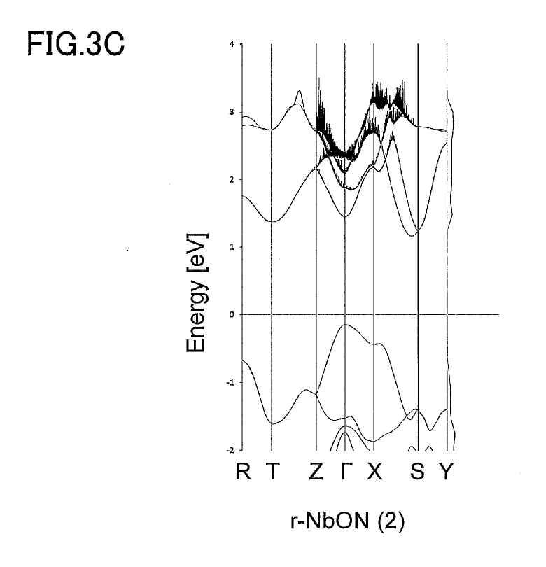

FIG. 4 shows a cross-sectional view of a semiconductor structure 100 which is an embodiment of the semiconductor structure of the present disclosure. The semiconductor structure 100 includes a substrate 110 and a r-NbON film 120 disposed on one principal surface of the substrate 110. The r-NbON film 120 is composed of a niobium oxynitride represented by the chemical formula NbON. The r-NbON film 120 has a rutile-type crystal structure. The r-NbON film 120 may be oriented in a particular direction such as the [110] direction. In other words, the r-NbON film 120 may have a particular orientation plane such as the (110) plane.

The substrate 110 is a substrate having at least one principal surface (the principal surface on which the r-NbON film 120 is to be disposed) composed of a rutile-type compound having a rutile-type crystal structure. The rutile-type compound of the substrate 110 may be oriented in the (110) plane. Examples of the substrate 110 include:

(1) a substrate composed of a rutile-type compound with (110) orientation; and

(2) a substrate having a layer composed of a rutile-type compound with (110) orientation, the layer forming at least one principal surface of the substrate.

Examples of the rutile-type compound include titanium oxide and tin oxide. That is, a titanium oxide substrate or a tin oxide substrate can be used as the substrate 110. The titanium oxide is represented by the chemical formula TiO₂, and the tin oxide is represented by the chemical formula SnO₂. Examples of the titanium oxide substrate include:

(1) a substrate composed of titanium oxide with (110) orientation; and

(2) a substrate having a layer composed of titanium oxide with (110) orientation, the layer forming at least one principal surface of the substrate.

That is, the titanium oxide substrate encompasses those obtained by forming a layer composed of titanium oxide with (110) orientation on a surface of a given substrate. The same applies to the tin oxide substrate.

(Method for Producing r-NbON Film)

First, a substrate having at least one principal surface composed of a rutile-type compound is prepared. That is, the substrate 110 described above is prepared. Next, a niobium oxynitride is grown by epitaxial growth on that principal surface of the substrate 110 which is composed of a rutile-type compound. The epitaxial growth can be carried out, for example, by a technique such as sputtering, molecular-beam epitaxy, pulsed laser deposition, or organometallic vapor phase epitaxy. When pulsed laser deposition is employed to carry out the epitaxial growth, it is conceivable, for example, to use a target composed of niobium oxide, laser-ablate the target, and grow the niobium oxynitride by a reaction of the laser-ablated target with oxygen and nitrogen radical.

### EXAMPLES

Hereinafter, the rutile-type niobium oxynitride and semiconductor structure of the present disclosure will be described in more detail with an example.

### Example 1

In Example 1, a semiconductor structure 100 as shown in FIG. 4 was fabricated. First, a rutile-type titanium oxide substrate 110 with (110) orientation was prepared. A tin oxide film with a thickness of 2 nm was formed on the titanium oxide substrate 110 by pulsed laser deposition while the titanium oxide substrate 110 was heated to 550° C. The target was composed of titanium oxide represented by the chemical formula TiO₂. The oxygen partial pressure was 1×10⁻⁵ Torr. Next, a r-NbON film 120 with a thickness of 40 nm was formed on the titanium oxide substrate 110 by pulsed laser deposition while the titanium oxide substrate 110 was heated to 650° C. The target was composed of niobium oxide represented by the chemical formula Nb₂O_{4.8}. The oxygen partial pressure was 1×10⁻⁶ Torr and the nitrogen partial pressure was 1×10⁻⁵ Torr. The nitrogen used for formation of the r-NbON film 120 was supplied in the form of nitrogen radical from a RE′ plasma source. The RE′ power was set to 350 W. The target was ablated by KrF excimer laser. The frequency of the laser was set to 3 Hz.

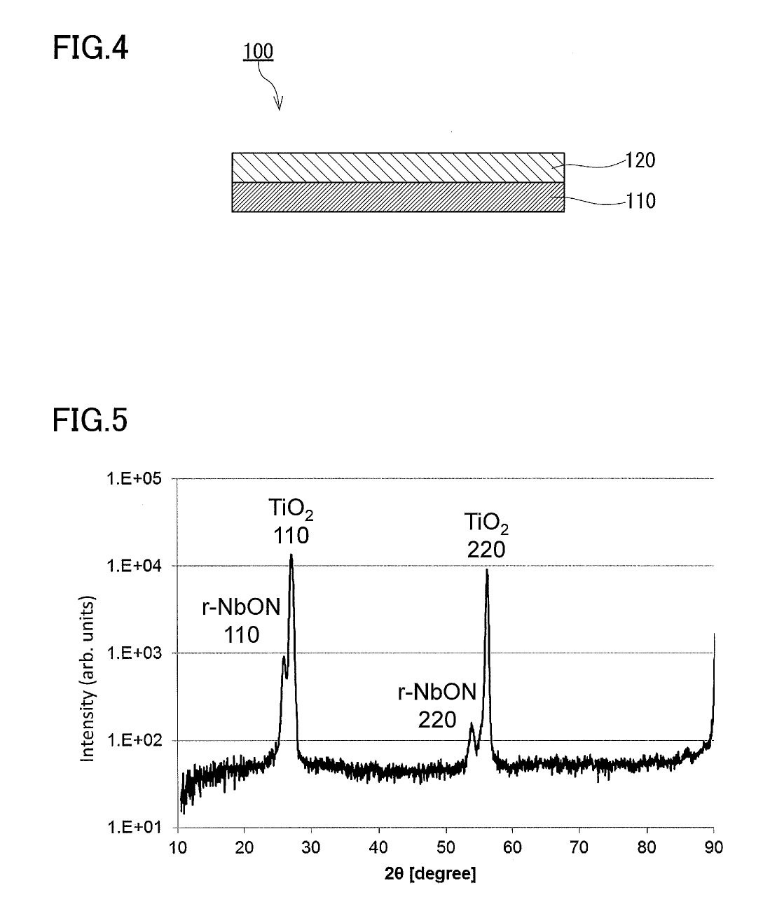

The r-NbON film 120 thus formed was subjected to X-ray diffraction analysis according to a 2θ-ω scan method. FIG. 5 shows the result of the 2θ-ω scan measurement of the r-NbON film 120 obtained in Example 1. As shown in FIG. 5, there were observed four peaks which were respectively the peak of the (110) plane of titanium oxide, the peak of the (220) plane of titanium oxide, the peak of the (110) plane attributed to r-NbON, and the peak of the (220) plane attributed to r-NbON. The position (26.0°) of the peak of the (110) plane of r-NbON approximately coincides with peak positions predicted by first-principles calculation (r-NbON (1): 26.7°, r-NbON (2): 26.5°). Likewise, the position (53.9°) of the peak of the (220) plane of r-NbON approximately coincides with peak positions predicted by first-principles calculation (r-NbON (1): 54.1°, r-NbON (2): 54.5°). As described above, only the peaks of the (110) and (220) planes attributed to r-NbON were observed, except for the two peaks attributed to the titanium oxide substrate. This confirmed that a r-NbON film 120 with (110) orientation was epitaxially grown on the titanium oxide substrate 110 with (110) orientation.

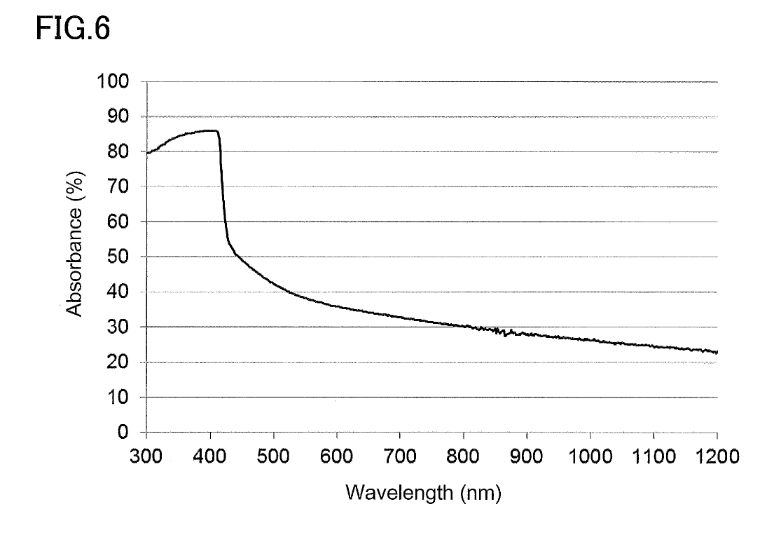

The light absorbance of the r-NbON film 120 of Example 1 was measured. The result of the measurement is shown in FIG. 6. As seen from FIG. 6, it was confirmed that the absorbance increases in the wavelength range of 400 nm to 700 nm. This confirmed that the r-NbON film 120 obtained in the present example is a semiconductor capable of absorbing visible light.

### INDUSTRIAL APPLICABILITY

The rutile-type niobium oxynitride of the present disclosure is capable of absorbing long-wavelength light and has the advantageous property of permitting easy movement of electrons and holes generated by photoexcitation. The rutile-type niobium oxynitride is therefore applicable to various technical fields; for example, the rutile-type niobium oxynitride can be used as an optical semiconductor material in an application that requires high efficiency of use of sunlight.

1. A rutile-type niobium oxynitride having a rutile-type crystal structure and represented by the chemical formula NbON.

2. The rutile-type niobium oxynitride according to claim 1, being a semiconductor.

3. The rutile-type niobium oxynitride according to claim 2, being an optical semiconductor.

4. The rutile-type niobium oxynitride according to claim 1, being oriented in a (110) plane.

5. A semiconductor structure comprising:
a substrate having at least one principal surface composed of a rutile-type compound having a rutile-type crystal structure; and
a rutile-type niobium oxynitride grown on the one principal surface of the substrate, wherein the rutile-type niobium oxynitride is as defined in claim 1.

6. The semiconductor structure according to claim 5, wherein the substrate is a titanium oxide substrate.

7. The semiconductor structure according to claim 5, wherein the rutile-type niobium oxynitride is oriented in a (110) plane.

8. The semiconductor structure according to claim 5, wherein the rutile-type compound of the substrate is oriented in a (110) plane.

9. A rutile-type niobium oxynitride production method for producing the rutile-type niobium oxynitride according to claim 1, the method comprising:
preparing a substrate having at least one principal surface composed of a rutile-type compound having a rutile-type crystal structure; and
growing a niobium oxynitride on the one principal surface of the substrate by epitaxial growth.

10. The rutile-type niobium oxynitride production method according to claim 9, wherein the epitaxial growth is carried out by pulsed laser deposition.

11. The rutile-type niobium oxynitride production method according to claim 10, wherein a target composed of niobium oxide is used, and the rutile-type niobium oxynitride is grown by a reaction of the target having been laser-ablated with oxygen and nitrogen radical.
